(19) United States
(12) Patent Application Publication
(10) Pub. No.: US 2004/0217013 A1
(43) Pub. Date: Nov. 4, 2004

(54) Apparatus and method for electropolishing a metal wiring layer on a semiconductor device

(75) Inventors: Sun-jung Lee, Kyungki-do (KR); Ki-chul Park, Suwon-city (KR)

Correspondence Address: Anthony P. Onello, Jr., MILLS & ONELLO LLP, Suite 605, Eleven Beacon Street, Boston, MA, 02108, US

(73) Assignee: Samsung Electronics Co., Ltd.

(21) Appl. No.: 10/814,381

(22) Filed: Mar. 31, 2004

(30) Foreign Application Priority Data
May 3, 2003 (KR) 03-28422

(51) Int. Cl. H01L 21/66; C25F 3/00; B23H 3/00

(52) U.S. Cl. 205/659; 438/466; 438/17; 438/687; 205/668

(57) ABSTRACT

The present invention relates to an apparatus and method for electropolishing a metal wire layer on a semiconductor device. To electropolish the metal wiring layer, a wafer is dipped into an electrolyte solution, and positive and negative voltages are applied to the wafer and electrodes, respectively. The electrodes include a main electrode and a plurality of auxiliary electrodes disposed above the main electrode. In a preferred embodiment, the plurality of auxiliary electrodes are mesh-type electrodes and are annular in shape and concentrically disposed, and thus the electrolyte solution can readily flow between them. Further, the metal wiring layer is preferably sequentially electropolished outwardly from the center of the wafer by sequentially applying negative voltages to the plurality of annular auxiliary electrodes. In this manner, a uniform electropolishing process is performed.

### BACKGROUND OF THE INVENTION

This application claims priority from Korean Patent Application No. 10-2003-0028422 filed on May 3, 2003 with the Korean Intellectual Property Office, the disclosure of which is incorporated herein by reference.

1. Field of the Invention

The present invention relates to an apparatus and method for electropolishing a metal wire layer on a semiconductor device, and more particularly, to an apparatus and method for polishing a metal wiring layer, i.e. a copper layer, using a plurality of annularly formed mesh-type negative electrodes.

2. Description of the Prior Art

As the minimum line width of semiconductor devices continues to decrease, problems such as an increase in the time delay of signals due to an increase in wiring resistance and electromigration due to increase in current density are generally produced. Until recently, easily workable aluminum, with its relatively low resistivity (3-4 μm/cm), has been widely used as a wiring material. Since the aforementioned issues such as wiring resistance and electromigration have become a problem due to decreasing line width and increase in wiring length, however, the use of aluminum as a wiring material in semiconductor devices has become limited. Thus, there has been a need for new wiring materials.

Among various metals, copper offers a low resistivity of 1.67 μm/cm and good electromigration resistance, and thus, through the use of copper, operating speed and reliability of devices can be maintained, even though the sectional area of a metal thin film is reduced. Accordingly, copper is most favorably used as a wiring material for very high-speed integrated circuits.

Methods for forming copper layers include a physical vapor deposition (PVD) process, a chemical vapor deposition (CVD) process, an electroless plating process, an electroplating process, and the like. However, in view of the quality of copper film and the need for burial of copper into contact holes, an electroplating technique in which a copper seed layer is first formed using the PVD method and the copper is then buried into the contact hole using the electroplating process has been the most widely researched among the techniques.

More specifically, in a general damascene process, an insulating layer is first formed on a wafer and a desired trench, contact hole or the like is then formed thereon using a patterning process. To prevent the copper from diff-using into the insulating layer, a diffusion barrier film is next formed. As a method for burying a wiring material such as copper into a semiconductor structure so constructed, an electroplating process is widely used. At this time, since the electroplating process requires conductive layers through which an electric current can flow so as to perform reduction of copper ions in the solution, the copper seed layer is first formed using the PVD process etc. and the copper is then deposited in the trench, contact hole or the like using the electroplating process.

Subsequently, primary chemical mechanical polishing (CMP) is used to remove excess copper layers on the pattern. Then, to remove the exposed diffusion barrier film, a secondary CMP is performed and the resultant wiring structure is completed.

If a considerable amount of a metal wiring layer is to be polished using a general CMP, a long polishing time period is required and a large quantity of slurry is also consumed, thereby leading to high production cost. According to the conventional approach, the chemical mechanical polishing process should be performed twice so as to form the resultant wiring structure. To this end, a great deal of time and cost are consumed in the process.

Studies for substituting the primary chemical mechanical polishing process with an electropolishing process have begun to address these problems. The electropolishing process removes deposited copper layers by reversing the electrodes used in the electroplating process. An important aspect of such a process is the need to uniformly remove the copper layers over the entire surface of the wafer.

The electropolishing process is generally performed by applying a positive voltage to a wafer and applying a negative voltage to an electrode positioned at a location adjacent to the wafer so that the electropolishing is conducted over the entire surface of the wafer. However, since the voltage is applied to an edge of the wafer when performing the electropolishing for a copper thin film, current density at the edge of the wafer is increased, whereas current density at the center of the wafer is greatly reduced. Thus, the thickness of the copper layer at the edge and center of the wafer remaining after the electropolishing process is finished is not uniform. This variation in thickness is illustrated in the chart of FIG. 1. Therefore, it is difficult to further remove the copper layer remaining at the wafer center. Consequently, since the copper layer, i.e. the metal wiring layer, on the semiconductor device, is not uniformly formed, the processing time required for any subsequent process is increased, leading to additional production costs.

According to the conventional approaches, in the case where the thickness of a copper layer over the entire surface of a wafer is not uniform due to variation in thickness of the wafer produced during the process of forming the copper wiring, as shown in FIG. 1, there is another problem in that the copper layer cannot be removed below the lowest thickness thereof.

### SUMMARY OF THE INVENTION

The present invention addresses the aforementioned problem where the thickness of a metal wiring layer on a wafer is not uniform when the metal wiring layer on the wafer is polished according to the aforementioned conventional electropolishing process. To this end, the present invention employs electrodes, which include a main electrode and a plurality of auxiliary electrodes disposed above the main electrode, in the electropolishing process and optionally uses mesh-type electrodes as the auxiliary electrodes. Thus, a system and method that employ the present invention are configured in such a manner that the metal wiring layer on the wafer is sequentially polished outwardly from the center of the wafer and that the mesh-type electrodes allow the electrolyte solution to flow smoothly. Accordingly, an object of the present invention is to provide an apparatus and method for electropolishing a metal wire layer on a semiconductor device wherein a uniform wiring layer can be obtained following the electropolishing process.

According to an aspect of the present invention for achieving the object, there is provided a method for electropolishing a metal wire layer on a semiconductor device, comprising the steps of immersing a wafer into an electrolyte solution to perform an electropolishing process, applying a positive voltage to the wafer, and applying negative voltages to electrodes which are disposed in the electrolyte solution and include a main electrode and a plurality of auxiliary electrodes.

According to another aspect of the present invention, there is provided an apparatus for electropolishing a metal wiring layer on a semiconductor device, comprising an electrolyte solution for polishing the metal wiring layer, a wafer chuck for holding the wafer in a polishing chamber containing the electrolyte solution, electrodes disposed within the electrolyte solution and the electrodes including a main electrode and a plurality of auxiliary electrodes, and power sources for supplying a positive voltage to the wafer and negative voltages to the electrodes.

In a preferred embodiment, the auxiliary electrodes are disposed above the main electrode, between the main electrode and the immersed wafer.

Preferably, the negative voltages are first applied to the main electrode and then to the plurality of auxiliary electrodes. More preferably, the negative voltages applied to the plurality of auxiliary electrodes are sequentially applied to the electrodes.

Further, the negative voltages may be applied to the main electrode and the auxiliary electrodes at the same time. Preferably, the negative voltages applied to the plurality of auxiliary electrodes are sequentially applied to the electrodes.

It is preferred that amount of polishing performed on each portion of a wafer be adjusted by causing current densities or voltages applied to the plurality of auxiliary electrodes to be different from one another.

It is also preferred that the plurality of auxiliary electrodes be mesh-type electrodes or be formed to be annular in shape and concentrically disposed.

Furthermore, it is preferred that the supply of negative voltages to the electrodes be stopped when the metal wiring layer formed on the wafer adjacent to the auxiliary electrodes is electropolished and the surface of a diffusion barrier film disposed below the metal wiring layer is exposed.

More preferably, the supply of negative voltages to the electrodes is stopped by measuring any one of the currents flowing between the wafer and the auxiliary electrodes or the thickness or optical reflectance of the relevant portions of the metal wiring layer on the wafer adjacent to the auxiliary electrodes.

In addition, the electrolyte solution preferably contains a phosphoric acid (H₃PO₄).

Preferably, the wafer is moved when the voltages are applied. More preferably, the wafer is rotated or horizontally shaken when the voltages are applied.

### BRIEF DESCRIPTION OF THE DRAWINGS

The above and other objects, advantages and features of the present invention will become apparent from the following description of a preferred embodiment given in conjunction with the accompanying drawings, in which:

FIG. 1 is a graph plotting the results of performing an electropolishing process for a metal wiring layer on a semiconductor device according to the conventional technique;

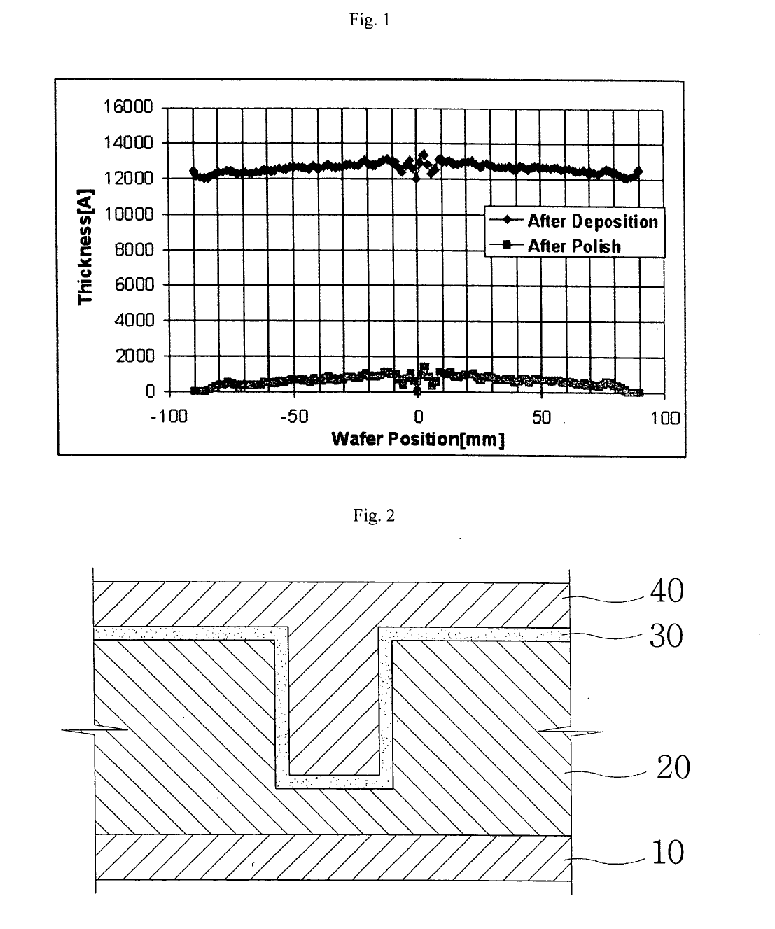

FIGS. 2-4 are sectional views illustrating the process of electropolishing a metal wiring layer on a semiconductor device according to the present invention; and

FIGS. 5 and 6 are views schematically showing the configuration of an apparatus for electropolishing the metal wiring layer on the semiconductor device according to the present invention.

### DETAILED DESCRIPTION OF PREFERRED EMBODIMENTS

Hereinafter, a preferred embodiment of an electropolishing apparatus and method according the present invention will be explained in detail with reference to the accompanying drawings.

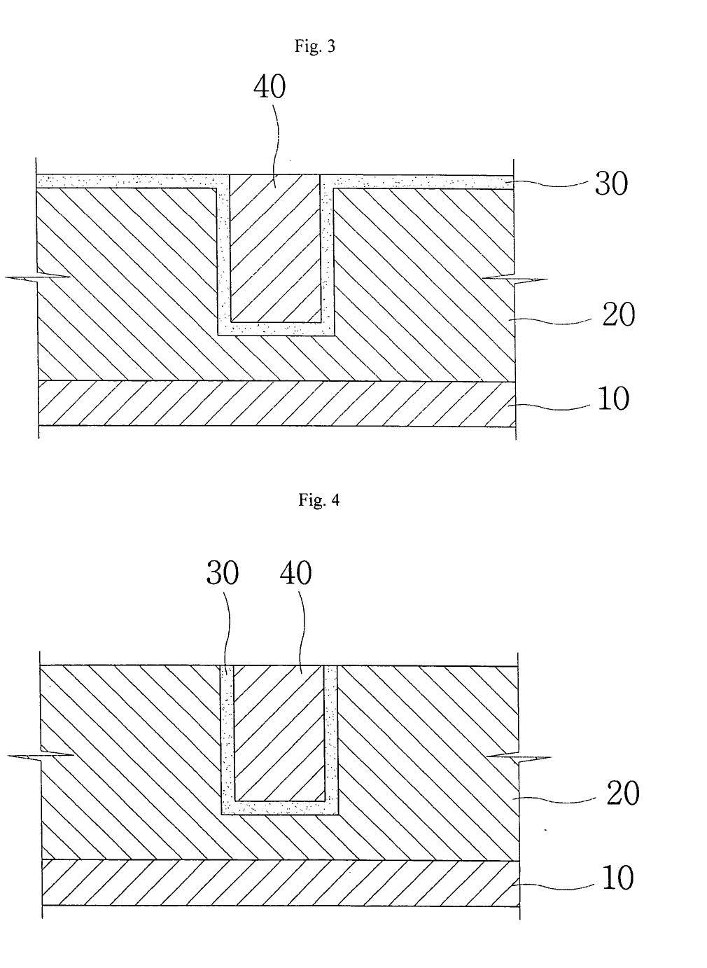

FIGS. 2-4 are sectional views illustrating the process of electropolishing metal wiring layers on semiconductor devices according to the present invention.

Referring to FIG. 2, a wafer 10 is preferably comprised of silicon. However, the wafer may optionally include other semiconductor materials such as gallium arsenide (GaAs) according to the application of the semiconductor device.

An insulating layer 20 is first formed on the wafer 10. Preferably, the insulating layer 20 employed in the present invention may comprise any dielectric material conventionally employed in the manufacture of semiconductor devices, both organic and inorganic, with a dielectric constant less than about 3.9, such as SiO₂, FSG, SiOC, SiOCH, OSG, BPSG, or TEOS. If a low dielectric constant material is employed in the insulating layer, the RC delay thereof is generally reduced and superior electrical insulation is provided.

After insulating layer 20 has been formed on the wafer 10, a damascene process can be used to form a metal wiring layer 40 thereon. In a general damascene process, the insulating layer 20 is first formed on the wafer 10, and a desired trench or contact hole is then formed thereon using a patterning process. Thereafter, a diffusion barrier film 30 is deposited thereon to prevent the metal wiring layer 40 from diffusing into the insulating layer 20. As a method for filling the metal wiring materials into the semiconductor structure so constructed, an electroplating process is widely used.

The diffusion barrier film 30 can be formed on the insulating layer 20 using a conventional deposition method such as physical vapor deposition (PVD), atomic layer deposition (ALD), chemical vapor deposition (CVD) or electroless plating. In the present invention, the diffusion barrier film 30 preferably includes titanium, titanium nitride, tantalum, tantalum nitride, tungsten, tungsten nitride, cobalt, or cobalt alloys.

In the preferred embodiment of the present invention, the metal wiring layer 40 preferably includes copper. Since the metal wiring layer 40 is formed on the diffusion barrier film 30, the copper is adequately prevented from diffusing from the metal wiring layer 40 into the insulating layer 20. According to the present invention, it is preferred that the metal wiring layer 40 include copper, but the metal wiring layer may also include electrically conductive materials other than copper. Additionally, if the metal wiring layer 40 is formed using the electroplating process disclosed in U.S. Pat. No. 6,176,992, which is entitled “Method and Apparatus for Electro Chemical Mechanical Deposition” and filed on Dec. 1, 1998, a uniform metal wiring layer can be formed as shown in FIG. 2.

Since an electroplating process requires a conductive layer through which an electric current can flow, so as to perform reduction of copper ions in the solution, a copper seed layer is formed using the PVD or CVD process and the copper is deposited into the trench, contact hole or the like using the electroplating process.

The metal wiring layer 40 is then removed using the electropolishing process in accordance with the present invention until the surface of the diffusion barrier film 30 is exposed, as shown in FIG. 3.

Subsequently, the diffusion barrier film 30 and metal wiring layer 40 are removed by chemical-mechanical polishing to form a resultant metal wiring layer on the semiconductor, as shown in FIG. 4.

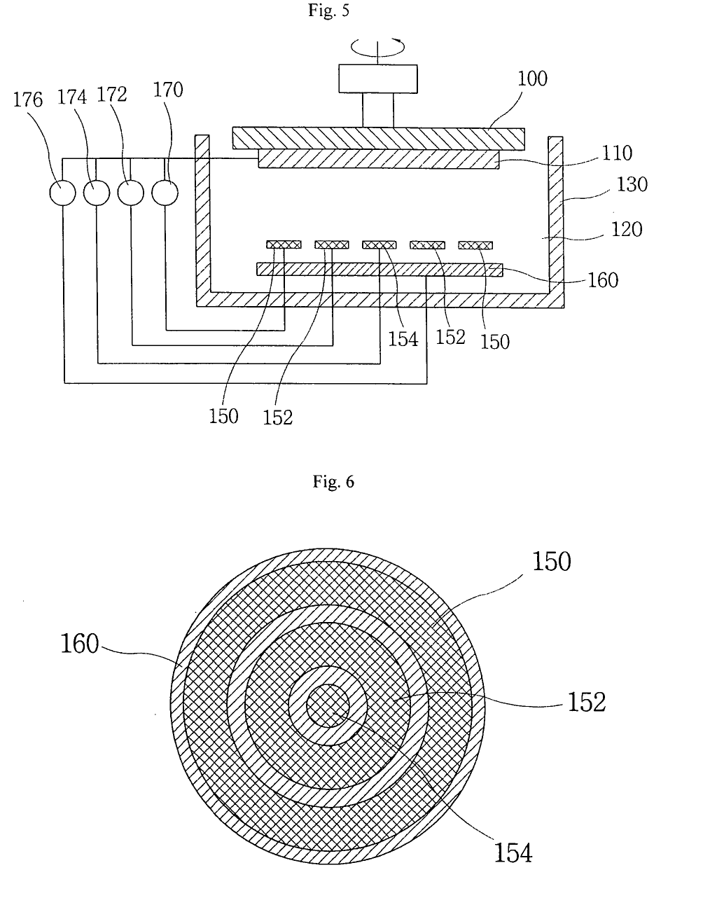

FIGS. 5 and 6 are views schematically showing the configuration of the apparatus for electropolishing the metal wiring layer on the semiconductor device according to the present invention.

As shown in FIG. 5, the apparatus for electropolishing a metal wiring layer comprises a wafer 110 with a metal wiring layer deposited thereon, an electrolyte solution 120 used for polishing the metal wiring layer, a wafer chuck 100 for causing the wafer 110 to be properly held and positioned within a polishing chamber 130 in which the wafer 110 and the electrolyte solution 120 are contained, electrodes which are disposed within the electrolyte solution 120 and include a main electrode 160 and a plurality of auxiliary electrodes 150, 152 and 154 for applying a predetermined voltage to the electrolyte solution 120 to electropolish the wafer 110, and power sources 170, 172, 174 and 176 for supplying positive voltages to the wafer 110 and negative voltages to the plurality of auxiliary electrodes 150, 152 and 154. In the preferred embodiment of the present invention, the electrolyte solution 120 flows into the polishing chamber 130 through a predetermined inlet (not shown) and is discharged through a predetermined outlet (not shown).

Herein, the electrode includes the main electrode 160 and a plurality of auxiliary electrodes 150, 152 and 154, which are disposed above the main electrode 160 with an insulator (not shown) interposed therebetween. However, although three auxiliary electrodes are shown in the illustration of the preferred embodiment of the present invention, any number of the auxiliary electrodes may be used in this embodiment of the present invention. In general, the more auxiliary electrodes used, the more uniform the electropolishing will be.

The power sources 170, 172, 174 and 176 can be operated in a direct current (DC) mode. Alternatively, the power sources 170, 172, 174 and 176 can be operated in a variety of pulse modes. In a case where a pulse mode voltage is applied, uniform electropolishing can be accelerated.

In general, the speed of metal ions moving from the wafer 110 is determined by current density used during polishing. Thus, the higher the current density used during polishing, the greater the electropolishing rate. In the preferred embodiment of the present invention, a current-density of about 10 to 60 mA/cm² can be used.

Further, the present invention may be configured in such a manner that a high current density during polishing is initially applied and is then gradually decreased over the course of the electropolishing process.

Negative voltages from the power sources 170, 172, 174 and 176 can be simultaneously applied to the plurality of auxiliary electrodes 150, 152 and 154, and the main electrode 160. Preferably, after the voltage from power source 176 is applied to the main electrode 160, voltages from power sources 170, 172 and 174 are applied to the plurality of auxiliary electrodes 150, 152 and 154. More preferably, voltages from power sources 170, 172 and 174 are sequentially applied to the plurality of auxiliary electrodes 150, 152 and 154. For example, when the metal wiring layer to be electropolished is thick, the voltage from power source 176 is first applied to the main electrode 176 so that the wiring layer can be polished to a predetermined thickness. Then, the voltage from power source 174 is applied to the center auxiliary electrode 154 to electropolish the layer, and subsequently, the voltages from power sources 174 and 176 are applied to the next outward auxiliary electrode 152 and then the outermost auxiliary electrode 150. Alternatively, the voltages may be applied to the auxiliary electrodes in an order reverse to the above, i.e., the voltages can be sequentially applied to the outermost, intermediate and center auxiliary electrodes 150, 152 and 154 to electropolish the layer.

In a case where voltages are sequentially applied the electrodes, the voltages may either be continuously supplied, or not supplied, if necessary, to the center auxiliary electrode 154 while, at the same time, applying a voltage to the auxiliary electrode 152 nearest the center auxiliary electrode 154 and then sequentially to the outer auxiliary electrodes. The profile of the current density across the wafer undergoing electropolishing can thus be adjusted. Alternatively, the amount of polishing performed on respective portions of a wafer may be adjusted by causing the currents or voltages applied to the center and outer auxiliary electrodes to be different from one another.

The electrolyte solution 120 of the present invention contains a general electropolishing liquid such as a phosphoric acid. The concentration and composition of the electrolyte solution 120 may vary according to a specific application thereof.

The plurality of electrodes 150, 152, 154 and 160 may include copper. Thus, the copper contained in the metal wiring layer 40 migrates toward the copper-containing electrodes 150, 152, 154 and 160 so that the electrodes can be electroplated.

As shown in FIG. 6, the plurality of auxiliary electrodes 150, 152 and 154 may comprise mesh-type electrodes. In such a case, the electrolyte solution 120 can readily flow between the wafer 110 and the plurality of auxiliary electrodes 150, 152 and 154. Further, the plurality of auxiliary electrodes 150, 152 and 154 are preferably formed in an annular shape so that they can be concentrically disposed. Alternatively, the plurality of auxiliary electrodes 150, 152 and 154 may be shaped into a polygon such as triangle or rectangle, or an ellipse.

Referring to FIG. 4, when the metal wiring layer 40 formed on the wafer 110 adjacent to the auxiliary electrodes 150, 152 and 154 is electropolished and the surface of the diffusion barrier film 30 disposed below the metal wiring layer 40 is externally exposed, the supply of voltage from power sources 170, 172 and 174 is stopped. That is, the time when the applied voltages from the respective power sources 170, 172 and 174 are cut off is determined, for example, by measuring the current flowing between the wafer 110 and the respective auxiliary electrodes 150, 152 and 154, or by measuring the thickness or optical reflectance of the relevant portions of the metal wiring layer 40 adjacent to the respective auxiliary electrodes 150, 152 and 154.

The wafer chuck 100 of the present invention causes the wafer 110 to be rotated or horizontally shaken when the voltages from power sources 170, 172, 174 and 176 are applied to the wafer 110. In such a case, the wafer 110 is preferably rotated and shaken horizontally at the same time. Since the electrolyte solution 120 can be brought into contact with the wafer 110 due to the rotation and shaking of the wafer 110, the wafer can be uniformly electropolished. In the preferred embodiment of the present invention, the wafer can be rotated at a speed of about 30 to 100 rpm.

According to the electropolishing process of the present invention, the copper layer formed on the wafer can be uniformly polished, and the electropolishing time and thus the production cost thereof can be reduced, as compared to when a considerable amount of metal is removed by the CMP process.

Although the present invention has been described in connection with the preferred embodiment, the preferred embodiment is intended not to be limited thereto. It will be understood by those skilled in the art that various changes or modifications may be made thereto without departing from the spirit and scope of the invention.

What is claimed is:

1. A method for electropolishing a metal wiring layer on a semiconductor device, comprising the steps of:
immersing a wafer into an electrolyte solution to perform an electropolishing process;
applying a positive voltage to the wafer; and
applying negative voltages to electrodes which are disposed in the electrolyte solution and include a main electrode and a plurality of auxiliary electrodes.

2. The method as claimed in claim 1, wherein the negative voltages are first applied to the main electrode and then to the plurality of auxiliary electrodes.

3. The method as claimed in claim 2, wherein the negative voltages applied to the plurality of auxiliary electrodes are sequentially applied to the electrodes.

4. The method as claimed in claim 1, wherein the negative voltages are applied to the main electrode and the auxiliary electrodes at the same time.

5. The method as claimed in claim 4, wherein the negative voltages applied to the plurality of auxiliary electrodes are sequentially applied to the electrodes.

6. The method as claimed in claim 1, wherein an amount of polishing performed at various regions portion of the wafer is adjusted by causing current or voltages applied to the plurality of auxiliary electrodes to be different from one another.

7. The method as claimed in claim 1, wherein the plurality of auxiliary electrodes are mesh-type electrodes.

8. The method as claimed in claim 1, wherein the plurality of auxiliary electrodes are annular in shape and concentrically positioned.

9. The method as claimed in claim 1, further comprising the step of stopping supply of negative voltages to the electrodes when the metal wiring layer formed on the wafer adjacent to the auxiliary electrodes is electropolished and a surface of a diffusion barrier film disposed below the metal wiring layer is exposed.

10. The method as claimed in claim 9, wherein the step of stopping the supply of negative voltages to the electrodes is performed by measuring currents flowing between the wafer and the auxiliary electrodes.

11. The method as claimed in claim 9, wherein the step of stopping the supply of negative voltages to the electrodes is performed by measuring respective thicknesses of relevant portions of the metal wiring layer on the wafer adjacent the auxiliary electrodes.

12. The method as claimed in claim 9, wherein the step of stopping the supply of negative voltages to the electrodes is performed by measuring respective optical reflectances of relevant portions on the wafer adjacent the auxiliary electrodes.

13. The method as claimed in claim 1, wherein the electrolyte solution contains phosphoric acid (H₃PO₄).

14. The method as claimed in claim 1, further comprising the step of moving the wafer when the voltages are applied.

15. The method as claimed in claim 14, wherein moving comprises rotating or horizontally shaking the wafer.

16. The method as claimed in claim 1 wherein the auxiliary electrodes are disposed above the main electrode.

17. An apparatus for electropolishing a metal wiring layer on a semiconductor device, comprising:
an electrolyte solution for polishing the metal wiring layer;
a wafer chuck for holding the wafer in a polishing chamber containing the electrolyte solution;
electrodes disposed within the electrolyte solution, the electrodes including a main electrode and a plurality of auxiliary electrodes; and
power sources for supplying a positive voltage to the wafer and negative voltages to the electrodes.

18. The apparatus as claimed in claim 17, wherein the negative voltages are first applied to the main electrode and then to the plurality of auxiliary electrodes.

19. The apparatus as claimed in claim 18, wherein the negative voltages applied to the plurality of auxiliary electrodes are sequentially applied to the electrodes.

20. The apparatus as claimed in claim 17, wherein the negative voltages are applied to the main electrode and the auxiliary electrodes at the same time.

21. The apparatus as claimed in claim 20, wherein the negative voltages applied to the plurality of auxiliary electrodes are sequentially applied to the electrodes.

22. The apparatus as claimed in claim 17, further comprising a means for adjusting amounts of polishing performed on each portion of the wafer by causing current or voltages applied to the plurality of auxiliary electrodes to be different from one another.

23. The apparatus as claimed in claim 17, wherein the plurality of auxiliary electrodes are mesh-type electrodes.

24. The apparatus as claimed in claim 17, wherein the plurality of auxiliary electrodes are annular in shape and disposed concentrically.

25. The apparatus as claimed in claim 17, further comprising a system for determining whether the metal wiring layer formed on the wafer adjacent to the auxiliary electrodes is electropolished and a surface of a diffusion barrier film disposed below the metal wiring layer is exposed, and in response, stopping the supply of negative voltages to the electrodes.

26. The apparatus as claimed in claim 25, wherein the system causes the supply of negative voltages to the electrodes to be stopped by measuring current flowing between the wafer and the auxiliary electrodes.

27. The apparatus as claimed in claim 25, wherein the system causes the supply of negative voltages to the electrodes to be stopped by measuring respective thicknesses of relevant portions of the metal wiring layer on the wafer adjacent the auxiliary electrodes.

28. The apparatus as claimed in claim 25, wherein the sensors cause the supply of negative voltages to the electrodes to be stopped by measuring optical reflectance of the wafer adjacent the auxiliary electrodes.

29. The apparatus as claimed in claim 17, wherein the electrolyte solution contains a phosphoric acid (H₃PO₄).

30. The apparatus as claimed in claim 17, wherein the wafer chuck further includes a driving mechanism for moving the wafer when the voltages are applied.

31. The apparatus as claimed in claim 30, wherein the driving mechanism causes the wafer to be rotated or horizontally shaken.
